(19) United States
(12) Patent Application Publication
(10) Pub. No.: US 2024/0429179 A1
(43) Pub. Date: Dec. 26, 2024

(54) SEMICONDUCTOR DEVICE AND MANUFACTURING METHOD OF THE SEMICONDUCTOR DEVICE

(71) Applicant: SK hynix Inc., Icheon-si Gyeonggi-do (KR)

(72) Inventor: Jae Ho KIM, Icheon-si Gyeonggi-do (KR)

(73) Assignee: SK hynix Inc., Icheon-si Gyeonggi-do (KR)

(21) Appl. No.: 18/517,781

(22) Filed: Nov. 22, 2023

(30) Foreign Application Priority Data
Jun. 21, 2023 (KR) 10-2023-0079763

(51) Int. Cl. H01L 23/00; H10B 41/10; H10B 41/27; H10B 41/50; H10B 43/10; H10B 43/27; H10B 43/50

(52) U.S. Cl. CPC H01L 23/562; H10B 41/10; H10B 41/27; H10B 41/50; H10B 43/10; H10B 43/27; H10B 43/50

(57) ABSTRACT

There are provided a semiconductor device and a manufacturing method of the semiconductor device. The semiconductor device includes: a substrate including a chip guard region; a stress relief pattern spaced apart from the substrate and disposed over the chip guard region; a dummy stack structure formed on the stress relief pattern; a conductive contact plug extending downwardly while penetrating the stress relief pattern; and a chip guard pattern in direct contact with the conductive contact plug while penetrating the dummy stack structure.

### CROSS-REFERENCE TO RELATED APPLICATION

The present application claims priority under 35 U.S.C. § 119(a) to Korean patent application number 10-2023-0079763 filed on Jun. 21, 2023, in the Korean Intellectual Property Office, the entire disclosure of which is incorporated by reference herein.

### BACKGROUND

### 1. Technical Field

Embodiments of the present disclosure generally relate to an electronic device, and more particularly, to a semiconductor device and a manufacturing method of the semiconductor device.

### 2. Related Art

A nonvolatile memory device is a memory device in which stored data is retained as it is even when power supply is interrupted. As the improvement of the degree of integration of two-dimensional nonvolatile memory devices in which memory cells are formed in the form of a single layer over a substrate reaches the limit, there has recently been proposed a three-dimensional nonvolatile memory device in which memory cells are stacked vertically over a substrate.

The three-dimensional nonvolatile memory device includes interlayer insulating layers and gate electrodes, which are alternately stacked, and channel layers penetrating the interlayer insulating layers and the gate electrodes, and memory cells are stacked along the channel layers. Various structures and various manufacturing methods have been developed so as to improve the operational reliability of such a nonvolatile memory device having a three-dimensional structure.

### SUMMARY

In accordance with an embodiment of the present disclosure, there is provided a semiconductor device including: a substrate including a chip guard region; a stress relief pattern spaced apart from the substrate and disposed over the chip guard region; a dummy stack structure formed on the stress relief pattern; a conductive contact plug extending downwardly while penetrating the stress relief pattern; and a chip guard pattern in direct contact with the conductive contact plug while penetrating the dummy stack structure.

In accordance with an embodiment of the present disclosure, there is provided a semiconductor device including: a substrate including a main chip region and a chip guard region; a source layer spaced apart from the substrate and disposed over the main chip region; a cell stack structure formed on the source layer; a stress relief pattern spaced apart from the substrate and disposed over the chip guard region; a dummy stack structure formed on the stress relief pattern; and a conductive contact plug extending downwardly while penetrating the stress relief pattern, wherein the stress relief pattern includes a doped silicon layer or an undoped silicon layer.

In accordance with an embodiment of the present disclosure, there is provided a method of manufacturing a semiconductor device, the method including: forming a source layer on a substrate including a main chip region and a chip guard region; forming insulating patterns penetrating the source layer of the chip guard region, thereby defining, as a stress relief pattern, the source layer between the insulating patterns; forming a conductive contact plug penetrating the stress relief pattern; forming a stack structure, in which first material layers and second material layers are alternately stacked, in the main chip region and the chip guard region over the source layer, stress relief pattern and the conductive contact plug; forming a trench for chip guard formation, which exposes the conductive contact plug while penetrating the stack structure of the chip guard region; and forming a chip guard pattern by filling the trench for chip guard formation with a conductive material.

### BRIEF DESCRIPTION OF THE DRAWINGS

Examples of embodiments will now be described more fully hereinafter with reference to the accompanying drawings; however, they may be embodied in different forms and should not be construed as limited to the embodiments set forth herein.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram schematically illustrating a semiconductor device in accordance with an embodiment of the present disclosure.

FIG. 2 is a plan view illustrating a semiconductor device in accordance with an embodiment of the present disclosure.

FIG. 3 is a sectional view illustrating a semiconductor device in accordance with an embodiment of the present disclosure.

FIGS. 4A, 4B, 4C, 4D, 4E, 4F, 4G, 4H, 4I, 4J, and 4K are plan and sectional views illustrating a manufacturing method of a semiconductor device in accordance with an embodiment of the present disclosure.

FIG. 5 is a block diagram illustrating a configuration of a memory system in accordance with an embodiment of the present disclosure.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Hereinafter, embodiments of the present disclosure will be described in detail with reference to the accompanying drawings in order for those skilled in the art to be able to readily implement the technical spirit of the present disclosure.

Embodiments provide a semiconductor device and a manufacturing method of the semiconductor device, in which a stress relief pattern is disposed on the bottom of a chip guard pattern disposed in a chip guard region, thereby improving the reliability of the semiconductor device.

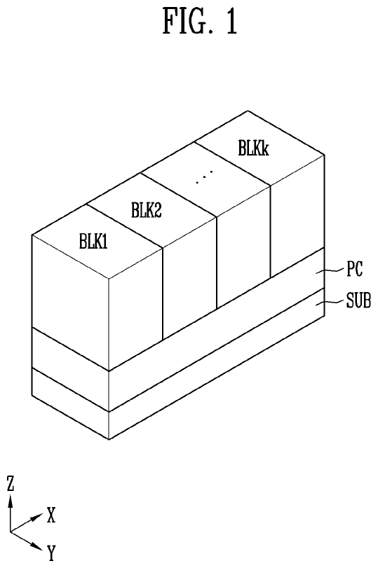

FIG. 1 is a block diagram schematically illustrating a semiconductor device in accordance with an embodiment of the present disclosure.

Referring to FIG. 1, the semiconductor device may include a peripheral circuit structure PC and memory blocks BLK1 to BLKk (k is a natural number of 2 or more), which are disposed on a substrate SUB. The memory blocks BLK1 to BLKk may overlap with the peripheral circuit structure PC.

The substrate SUB may be a single crystalline semiconductor layer. For example, the substrate SUB may be a bulk silicon substrate, a silicon on insulator substrate, a germanium substrate, a germanium on insulator substrate, a silicon-germanium substrate, or an epitaxial thin film formed through a selective epitaxial growth process.

The peripheral circuit structure PC may include a row decoder, a column decoder, a page buffer, a control circuit, and the like, which constitute a circuit for controlling operations of the memory blocks BLK1 to BLKk. For example, the peripheral circuit structure PC may include an NMOS transistor, a PMOS transistor, a resistor, a capacitor, and the like, which are electrically connected to the memory blocks BLK1 to BLKk. The peripheral circuit structure PC may be disposed between the substrate SUB and the memory blocks BLK1 to BLKk. That is, the peripheral circuit structure PC and the memory blocks BLK1 to BLKk may be sequentially stacked in a vertical direction Z on the substrate SUB. However, an embodiment in which the peripheral circuit structure PC extends to another region of the substrate SUB, which does not overlap with the memory blocks BLK1 to BLKk, is not excluded.

Each of the memory blocks BLK1 to BLKk may include impurity doped regions, bit lines, cell strings electrically connected to the impurity doped regions and the bit lines, word lines electrically connected to the cell strings, and select lines electrically connected to the cell strings. Each of the cell strings may include memory cells and select transistors, which are connected in series by a channel structure. Each of the select lines may be used as a gate electrode of a select transistor corresponding thereto, and each of the word lines may be used as a gate electrode of a memory cell corresponding thereto. The memory blocks BLK1 to BLKk may be sequentially arranged in a first horizontal direction X. However, the present disclosure is not limited thereto, and the memory blocks BLK1 to BLKk may be sequentially arranged in a second horizontal direction Y or be regularly arranged on an XY plane.

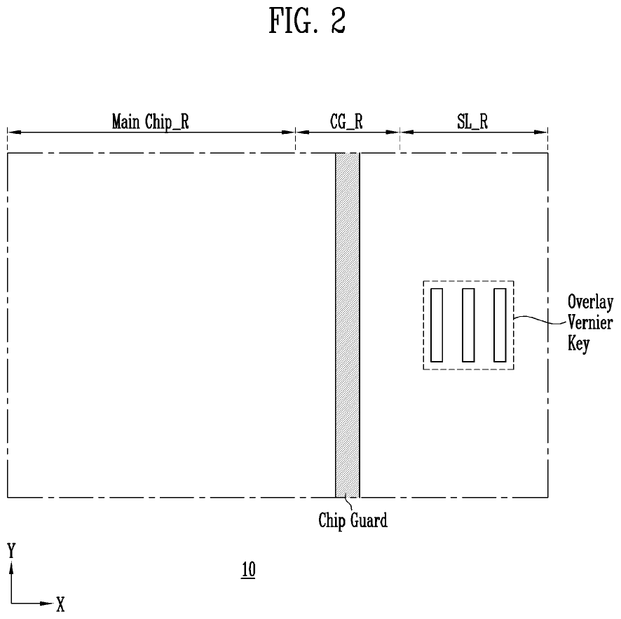

FIG. 2 is a plan view illustrating a semiconductor device in accordance with an embodiment of the present disclosure.

Referring to FIG. 2, the semiconductor device 10 may be defined into a main chip region Main Chip_R, a scribe line region SL_R, and a chip guard region CG_R between the main chip region Main Chip_R and the scribe line region SL_R.

Memory blocks (BLK1 to BLKk shown in FIG. 1) including a plurality of memory cells and a peripheral circuit structure (PC shown in FIG. 1) for driving the plurality of memory cells may be formed in the main chip region Main Chip_R.

An overlay vernier key for aligning a plurality of masks used in a manufacturing process of the semiconductor device may be disposed on the scribe line region SL_R.

At least one chip guard pattern Chip Guard may be disposed in the chip guard region CG_R between the main chip region Main Chip_R and the scribe line region SL_R. When at least two chip guard patterns Chip Guard are disposed, the chip guard patterns Chip Guard may be disposed in parallel to each other, and a buffer slit (not shown) may be formed in a space between the chip guard patterns Chip Guard.

The at least one chip guard pattern Chip Guard may be disposed in a line shape extending in the second horizontal direction Y. In an embodiment, the at least one chip guard pattern Chip Guard may block cracks from being spread toward the main chip region Main Chip_R in a sawing process of cutting the scribe region SL_R, and block an impurity from being introduced through an oxide layer exposed by a cut surface. In addition, in an embodiment, the bottom of the at least one chip guard pattern Chip Guard may be connected to a conductive contact plug, to be used as a path for discharging abnormal charges accumulated in the semiconductor device.

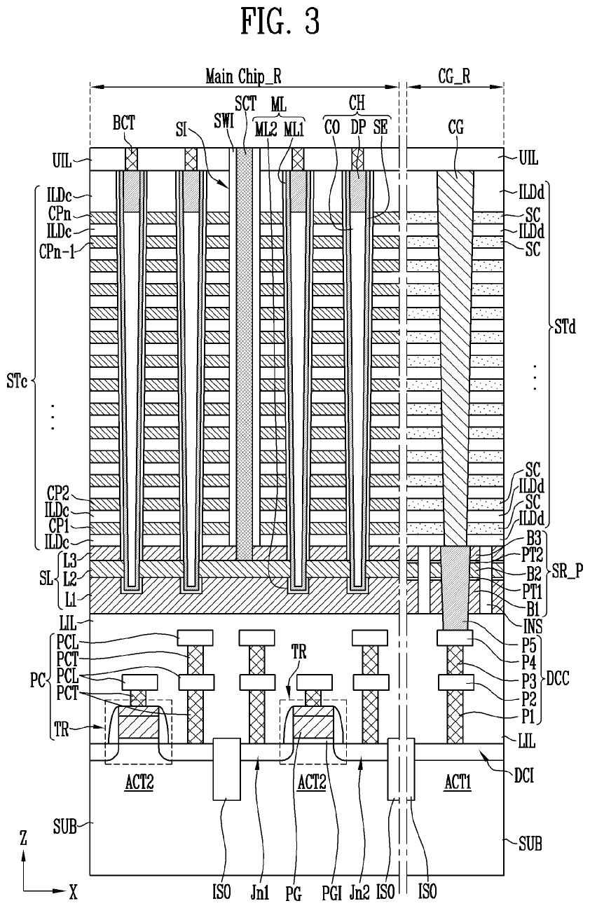

FIG. 3 is a sectional view illustrating a semiconductor device in accordance with an embodiment of the present disclosure.

Referring to FIG. 3, the semiconductor device may include a source layer SL disposed on a main chip region Main Chip_R of a substrate SUB, a cell stack structure STc disposed on the source layer SL, a plurality of channel structures CH extending in the vertical direction Z in the cell stack structure STc, a stress relief pattern SR_P disposed on a chip guard region CG_R of the substrate SUB, a dummy stack structure STd disposed on the stress relief pattern SR_P, a chip guard pattern CG extending in the vertical direction Z in the dummy stack structure STd, and a conductive contact plug DCC which is in contact with a lower surface of the chip guard pattern CG and extends downwardly (i.e., opposite the vertical direction Z) while penetrating the stress relief pattern SR_P.

The substrate SUB may be formed of the same material as the substrate SUB described above with reference to FIG. 1. Conductivity type dopants defining a well region may be implanted into the substrate SUB. Each of the conductivity type dopants defining the well region may be an n-type or p-type impurity. The well region of the substrate SUB may be divided into active regions ACT1 and ACT2 partitioned by isolation layers ISO. The isolation layers ISO may include an insulating material embedded in the substrate SUB. The active regions ACT1 and ACT2 may include a first active region ACT1 overlapping with the conductive contact plug DCC in the chip guard region CG_R and at least one second active region ACT2 overlapping with the cell stack structure STc in the main chip region Main Chip_R.

A peripheral circuit structure PC may include at least one transistor TR as described above with reference to FIG. 1. The transistors TR may include a peripheral gate insulating layer PGI disposed on the second active region ACT2, a peripheral-gate electrode PG disposed on the peripheral-gate insulating layer PGI, and first and second junctions Jn1 and Jn2 disposed in the second active region ACT2 at both sides of the peripheral-gate electrode PG. The first and second junctions Jn1 and Jn2 are regions defined by implanting an n-type or p-type impurity into the second active region ACT2. One of the first and second junctions Jn1 and Jn2 may be used as a source junction, and the other of the first and second junctions Jn1 and Jn2 may be used as a drain junction.

The peripheral circuit structure PC may include connection lines PCL and peripheral-contact plugs PCT, which are connected to the transistor TR. The peripheral circuit structure PC may include a resistor, a capacitor, and the like as described with reference to FIG. 1, in addition to the transistor TR and the connection lines PCL and the peripheral-contact plugs PCT, which are connected thereto.

A conductivity type impurity may be implanted into the first active region ACT1. In an embodiment, a discharge impurity region DCI may be defined in the first active region ACT1. The discharge impurity region DCI may include conductivity type impurities for forming a PN diode. The discharge impurity region DCI may be used as a path for discharging abnormal charges accumulated in the semiconductor device.

The above-described peripheral circuit structure PC may be covered with a lower insulating structure LIL disposed between the source layer SL and the substrate SUB. The lower insulating structure LIL may extend to cover the discharge impurity region DCI. The lower insulating structure LIL may include insulating layers stacked in a multi-layer structure.

The source layer SL may be disposed to be spaced apart from the substrate SUB by the peripheral circuit structure PC and the lower insulating structure LIL.

The source layer SL may be disposed on the lower insulating structure LIL of the main chip region Main Chip_R. The source layer SL may include two or more semiconductor layers L1, L2, and L3.

For example, the source layer SL may include first to third semiconductor layers L1 to L3 sequentially stacked on the lower insulating structure LIL. Each of the first and second semiconductor layers L1 and L2 may be a doped semiconductor layer including a source dopant. In an embodiment, each of the first and second semiconductor layers L1 and L2 may include a doped silicon layer including an n-type impurity. The third semiconductor layer L3 may be omitted in some cases. The third semiconductor layer L3 may include any one of an n-type doped silicon layer and an undoped silicon layer.

The stress relief pattern SR_P may be disposed on the lower insulating structure LIL of the chip guard region CG_R. The stress relief pattern SR_P may be configured to include first to third buffer patterns B1 to B3 and include protective layers PT1 and PT2 stacked between the first to third buffer patterns B1 to B3. Each of the first to third buffer patterns B1 to B3 may include a doped silicon layer or an undoped silicon layer, and each of the protective layers PT1 and PT2 may include an oxide layer. The first buffer pattern B1 may be made of the same material as the first semiconductor layer L1, and the third buffer pattern B3 may be made of the same material as the third semiconductor layer L3. The first buffer pattern B1, the second buffer pattern B2, and the third buffer pattern B3 may be sequentially stacked in the vertical direction Z.

The source layer SL and the stress relief pattern SR_P may be disposed at the same level.

The stress relief pattern SR_P may be penetrated by the conductive contact plug DCC. The conductive contact plug DCC may penetrate the lower insulating structure LIL to be in contact with the discharge impurity region DCI of the substrate SUB. The conductive contact plug DCC may be in direct contact with the discharge impurity region DCI and the stress relief pattern SR_P. A sidewall of the conductive contact plug DCC may be in direct contact with the stress relief pattern SR_P. An insulating pattern INS may be disposed on an outer wall of the stress relief pattern SR_P. The insulating pattern INS may include an oxide layer. The insulating pattern INS may allow the source layer SL disposed to extend from the main chip region Main Chip_R to the chip guard region CG_R and the conductive contact plug DCC to be electrically spaced apart from each other.

The conductive contact plug DCC may include first to fifth patterns P1 to P5 which are sequentially stacked. The first pattern P1 and the third pattern P3 may be disposed inside the lower insulating structure LIL, and be respectively disposed at levels at which the peripheral-contact plugs PCT are disposed. The second pattern P2 and the fourth pattern P4 may be disposed inside the lower insulating structure LIL, and be respectively disposed at levels at which the connection lines PCL are disposed. The fifth pattern P5 may penetrate the stress relief pattern SR_P, and extend to the inside of the lower insulating structure LIL to be in contact with the fourth pattern P4.

The dummy stack structure STd may overlap with the stress relief pattern SR_P and the insulating pattern INS. The dummy stack structure STd may include dummy interlayer insulating layers ILDd and sacrificial insulating layers SC.

The chip guard pattern CG may be in direct contact with the conductive contact plug DCC while penetrating the dummy stack structure STd in the vertical direction Z. The chip guard pattern CG may include a conductive material.

The cell stack structure STc may include cell interlayer insulating layers ILDc and conductive patterns CP1 to CPn (n is a natural number of 2 or more), which are alternately stacked on the source layer SL. The cell stack structure STc may be disposed at the same level as the dummy stack structure STd. The cell interlayer insulating layers ILDc may be disposed at the same levels as the dummy interlayer insulating layers ILDd, and the conductive patterns CP1 to CPn may be disposed at the same levels as the sacrificial insulating layers SC.

The cell interlayer insulating layers ILDc and the dummy interlayer insulating layers ILDd may be formed of the same material, and be formed through the same process. The sacrificial insulating layers SC may be formed of a material having an etching rate different from an etching rate of each of the cell interlayer insulating layers ILDc and the dummy interlayer insulating layers ILDd. For example, the cell interlayer insulating layers ILDc and the dummy interlayer insulating layers ILDd may include silicon oxide, and the sacrificial insulating layers SC may include silicon nitride.

Each of the conductive patterns CP to CPn may include various conductive materials such as a doped silicon layer, a metal layer, a metal silicide layer, and a barrier layer, and include two or more kinds of conductive materials. For example, each of the conductive patterns CP to CPn may include tungsten and a titanium nitride layer (TiN) surrounding the surface of the tungsten. In an embodiment, the tungsten is a low resistance metal, and may reduce the resistance of the conductive patterns CP1 to CPn. The titanium nitride layer TIN is a barrier layer, and may prevent or mitigate direct contact between the tungsten and the cell interlayer insulating layers ILDc.

The conductive patterns CP1 to CPn may be used as gate electrodes of a cell string. The gate electrodes of the cell string may include source select lines, word lines, and drain select lines. The source select lines are used as gate electrodes of the source select transistors, the drain select lines are used as gate electrodes of the drain select transistor, and the word lines are used as gate electrodes of memory cells.

The cell stack structure STc may surround each of the channel structures CH. That is, the channel structure CH may extend to the inside of the source layer SL to a certain depth while penetrating the cell stack structure STC. The channel structure CH may include a channel semiconductor pattern SE. The channel semiconductor pattern SE may include a silicon layer. A central region of the channel semiconductor pattern SE may be filled with a core insulating layer CO. The core insulating layer CO may be formed with a height lower than a height of the channel semiconductor pattern SE. An upper central region of the channel semiconductor pattern SE extending upwardly of the core insulating layer CO may be filled with a doped semiconductor pattern DP disposed on the core insulating layer CO. The doped semiconductor pattern DP may include an n-type doped silicon layer. The channel semiconductor pattern SE of the channel structure CH may be used as a channel region of the cell string, and the doped semiconductor pattern DP of the channel structure may be used as a drain junction of the cell string. A sidewall of the channel structure CH may be surrounded by a memory layer ML.

The channel structure CH may penetrate the cell stack structure STc and extend to the inside of the source layer SL. A partial sidewall of the channel structure CH may be in direct contact with the source layer SL. In an embodiment, the second semiconductor layer L2 of the source layer SL may be in direct contact with a sidewall of the channel semiconductor pattern SE. The memory layer ML may be divided into a first memory pattern ML1 and a second memory pattern ML2 by the second semiconductor layer L2. The first memory pattern ML1 may be disposed between the channel structure CH and the cell stack structure STc, and extend between the channel structure CH and the third semiconductor layer L3. The second memory pattern ML2 may be disposed between the channel structure CH and the first semiconductor layer L1.

A slit SI may be filled with a source contact structure SCT. The source contact structure SCT may be spaced apart from the cell stack structure STc by a sidewall insulating layer SWI formed on a sidewall of the slit SI. The sidewall insulating layer SWI may be penetrated by the source contact structure SCT. The source contact structure SCT may extend to be in contact with the source layer SL. The source contact structure SCT may include a single conductive material or two or more kinds of conductive materials. The conductive material for the source contact structure SCT may include a doped silicon layer, a metal layer, a metal silicide layer, a barrier layer, and the like. For example, the source contact structure SCT may include a doped silicon layer in contact with the source layer and a metal layer disposed on the doped silicon layer.

An upper insulating structure UIL may include a single insulating layer or two or more insulating layers. For example, the upper insulating structure UIL may include an oxide layer. The upper insulating structure UIL may be penetrated by a bit line contact plug BCT. The bit line contact plug BCT may be connected to the doped semiconductor pattern DP of the channel structure CH.

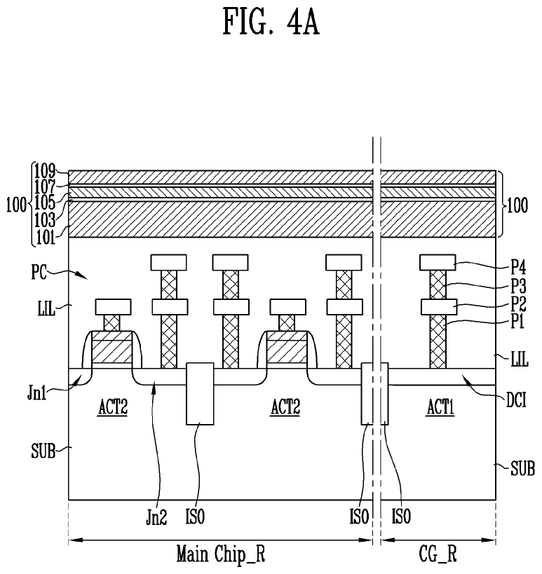

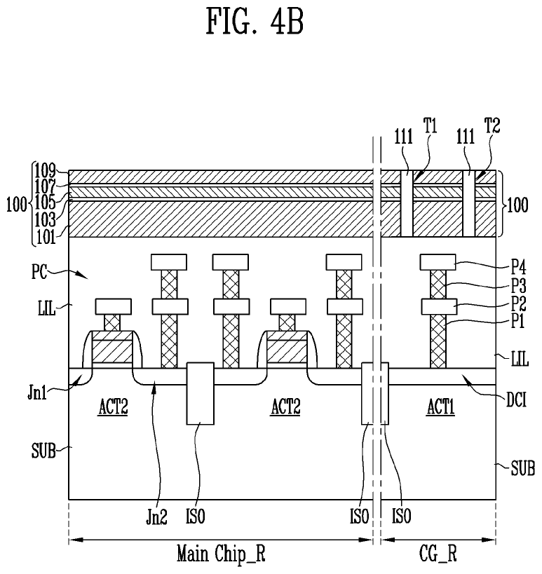

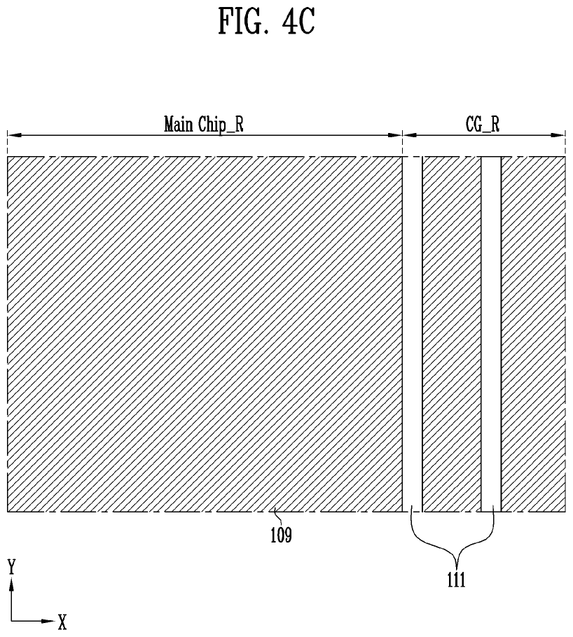

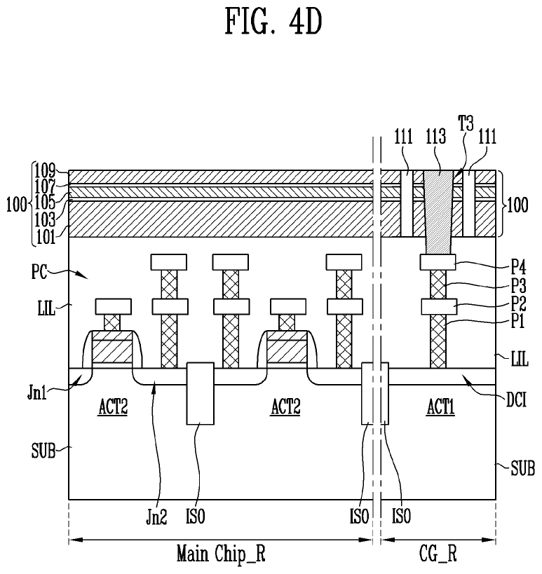

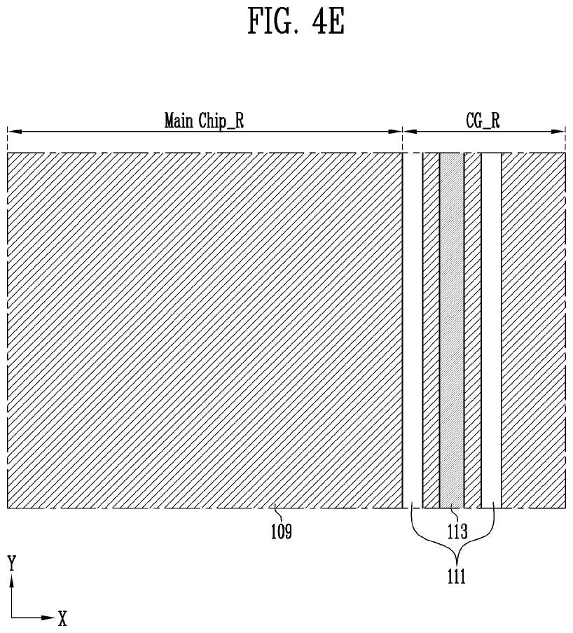

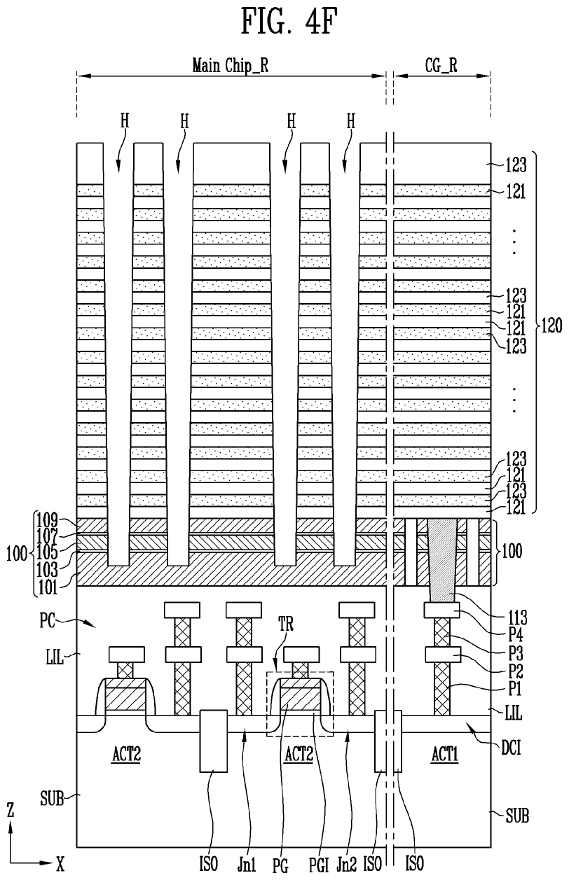

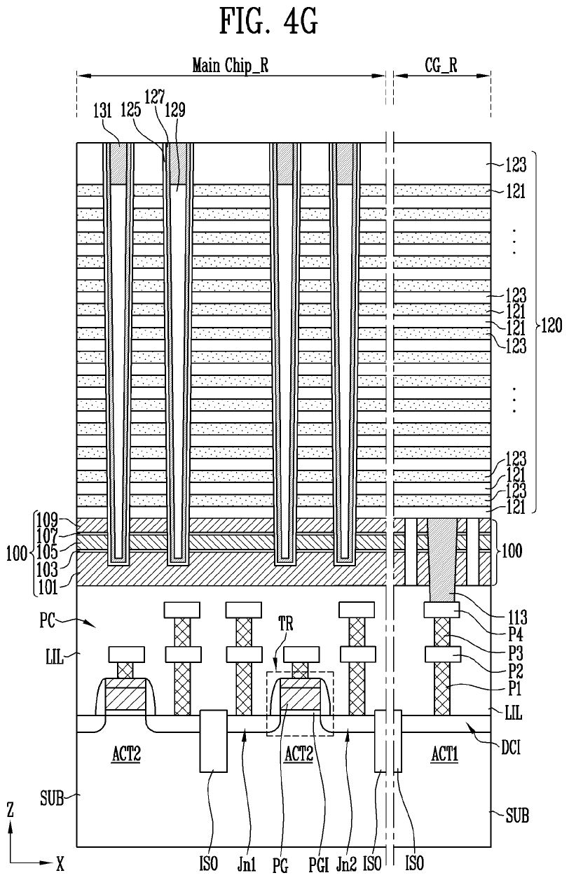

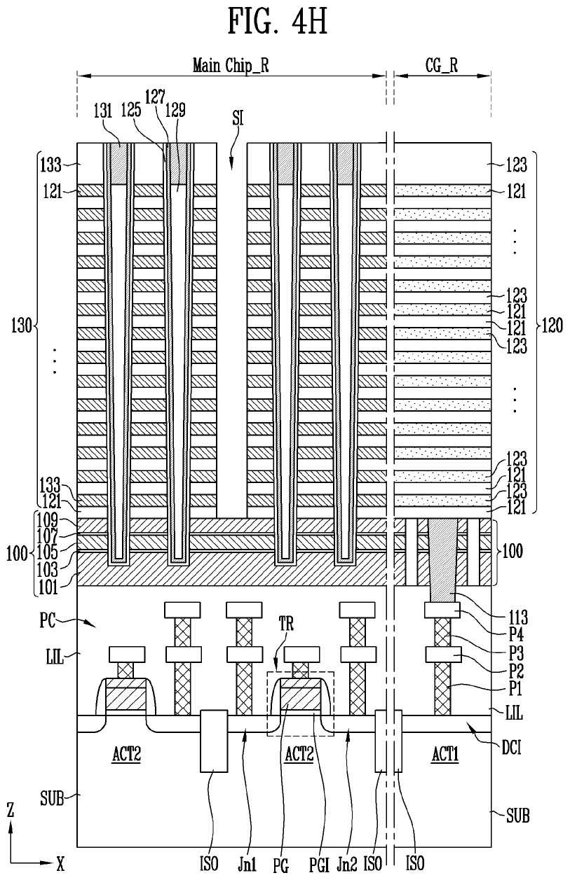

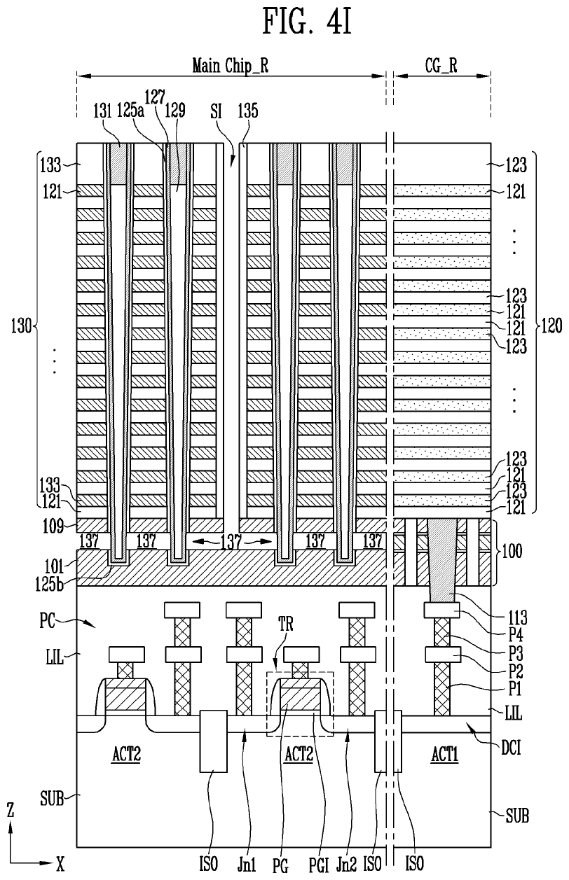

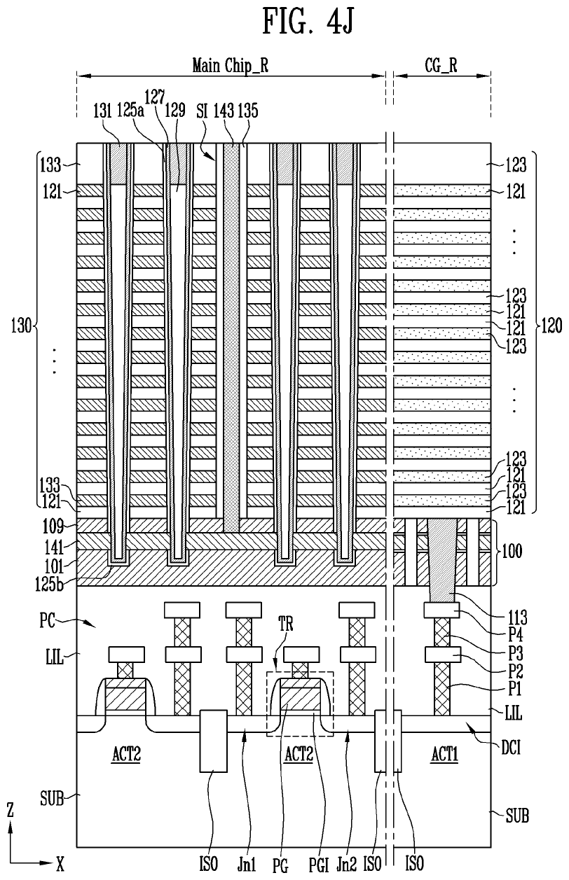

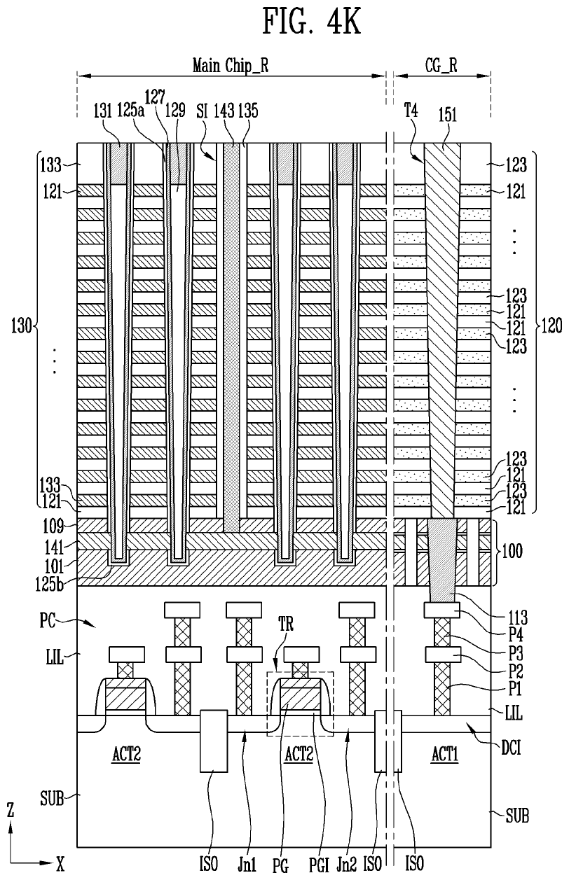

FIGS. 4A to 4K are plan and sectional views illustrating a manufacturing method of a semiconductor device in accordance with an embodiment of the present disclosure.

Referring to FIG. 4A, a peripheral circuit structure PC and first to fourth patterns P1 and P4 may be formed on a substrate SUB including active regions ACT1 and ACT2 partitioned by isolation layers ISO. The peripheral circuit structure PC and the first to fourth patterns P1 and P4 may be covered with a lower insulating structure LIL.

The active regions ACT1 and ACT2 may include a first active region ACT1 and at least one second active region ACT2. The first active region ACT1 may include a discharge impurity region DCI, and the second active region ACT may include junctions Jn1 and Jn2. A region overlapping with the first active region ACT1 may be defined as a discharge contact region, and a region overlapping with the second active region ACT2 may be defined as cell region.

The isolation layers ISO, the active regions ACT1 and ACT2, the discharge impurity region DCI, the junctions Jn1 and Jn2, the peripheral circuit structure PC, and the lower insulating structure LIL have been described above in detail with reference to FIGS. 1 and 3, and therefore, their repeated descriptions will be omitted.

The first to fourth patterns P1 to P4 may be formed of a conductive material, and be sequentially stacked on the discharge impurity region DCI. The first pattern P1 disposed in a lowermost layer among the first to fourth patterns P1 to P4 may be in direct contact with the discharge impurity region DCI.

Subsequently, a lower stack structure 100 may be formed on the lower insulating structure LIL. The lower stack structure 100 may include a lower semiconductor layer 101, a sacrificial layer 105, and an upper semiconductor layer 109, which are sequentially stacked. Before the sacrificial layer 105 is deposited on the lower semiconductor layer 101, a first protective layer 103 may be formed on the lower semiconductor layer 101. Before the upper semiconductor layer 109 is formed on the lower semiconductor layer 101 or the first protective layer 103, a second protective layer 107 may be formed on the lower semiconductor layer 101 or the first protective layer 103.

The lower semiconductor layer 101 may include a doped semiconductor layer including a conductivity type impurity. For example, the lower semiconductor layer 101 may include an n-type doped silicon layer. The sacrificial layer 105 may include a material having an etching rate different from an etching rate of each of the first protective layer 103 and the second protective layer 107, and each of the first protective layer 103 and the second protective layer 107 may include a material having an etching rate different from an etching rate of each of the lower semiconductor layer 101 and the upper semiconductor layer 109. For example, the sacrificial layer 105 may include an undoped silicon layer, and each of the first protective layer 103 and the second protective layer 107 may include an oxide layer. The upper semiconductor layer 109 may include a semiconductor layer. For example, the upper semiconductor layer 100 may include a doped silicon layer or an undoped silicon layer.

Referring to FIGS. 4B and 4C, a first trench T1 and a second trench T2 may be formed, which expose the lower insulating structure LIL while penetrating a portion of the lower stack structure 100 overlapping with a chip guard region CG_R. The first trench T1 and the second trench T2 may be formed to be spaced apart from a conductive contact plug formed in a subsequent process at a certain distance. After that, insulating patterns 111 may be formed by filling the inside of the first trench T1 and the second trench T2 with an insulating material.

The lower stack structure 100 formed on a main chip region Main Chip_R and the lower stack structure 100 between the insulating patterns 111 may be physically and electrically spaced apart from each other by the insulating patterns 111.

When the conductive contact plug formed in the subsequent process is formed to extend in a line shape in the second horizontal direction Y, each of the insulating patterns 111 in the first trench T1 and the second trench T2 may be formed at a position at which each of the insulating patterns 111 is spaced apart from the conductive contact plug at a certain distance to extend in a line shape in the second horizontal direction Y.

The lower stack structure 100 disposed between the first trench T1 and the second trench T2 may be defined as a stress relief pattern. For example, the lower semiconductor layer 101, the sacrificial layer 105 and the upper semiconductor layer 109, which are disposed between the first trench T1 and the second trench T2, may be defined as a first buffer pattern, a second buffer pattern, and a third buffer pattern, respectively. Accordingly, the stress relief pattern may include first to third buffer patterns 101, 105, and 109 each including a doped silicon layer or an undoped silicon layer.

In another embodiment, when the conductive contact plug is formed in a cylindrical shape, one trench ring spaced apart from the conductive contact plug at a certain distance may be formed in a ring shape to surround the circumference of the conductive contact plug, and an insulating pattern may be formed by filling an insulating material in the one trench. The insulating pattern may have a ring shape.

Referring to FIGS. 4D and 4E, a third trench T3 or a hole may be formed, which exposes the lower insulating structure LIL while penetrating a portion of the stress relief pattern 100 between the insulating patterns 111. The third trench T3 or the hole may extend to the inside of the lower insulating structure LIL to a certain depth. The third trench T3 or the hole may expose the fourth pattern P4 disposed in an uppermost layer among the first to fourth patterns P1 to P4.

After that, a conductive pattern 113 may be formed such that the third trench T3 or the hole is filled therewith. A diffusion barrier formed along a bottom surface and a sidewall of the third trench T3 or the hole may be formed before the conductive pattern 113 is formed.

The conductive pattern 113 may be directly connected to the fourth pattern P4. Accordingly, the first to fourth patterns P1 to P4 and the conductive pattern 113 may constitute a conductive contact plug P1 to P4 and 113 connected to the discharge impurity region DCI.

A sidewall of the conductive pattern 113 may be in contact with the stress relief pattern 100, i.e., the first to third buffer patterns 101, 105, and 109. The sidewall of the conductive pattern 113 may be surrounded by the first to third buffer patterns 101, 105, and 109.

Referring to FIG. 4F, a stack structure 120 may be formed on the top of the lower stack structure 100 of the main chip region Main Chip_R and the top of the insulating patterns 111, the conductive pattern 113, and the third buffer pattern 109 of the chip guard region CG_R. That is, the stack structure 120 may be formed on the top of the entire structure.

The stack structure 120 may include first material layers 121 and second material layers 123, which are alternately stacked.

The first material layers 121 may include a material different from a material of the second material layers 123. In an embodiment, the first material layers 121 may include an insulating material, and the second material layers 123 may include a sacrificial material having an etching rate different from an etching rate of the first material layers 121. For example, each of the first material layers 121 may include silicon oxide, and each of the second material layers 123 may include silicon nitride.

After that, channel holes H may be formed, which expose the lower semiconductor layer 101 while penetrating the stack structure 120 of the main chip region Main Chip_R. The channel holes H may extend to the inside of the lower semiconductor layer 101 to a certain depth. That is, the channel holes H may be formed to extend to the inside of the lower semiconductor layer 101 to a certain depth while penetrating the stack structure 120, the upper semiconductor layer 109, the second protective layer 107, the sacrificial layer 105, and the first protective layer 103.

Referring to FIG. 4G, a memory layer 125 may be conformally formed on a surface of each of the channel holes (H shown in FIG. 4F). The memory layer 125 may include a tunnel insulating layer, a data storage layer, and a blocking insulating layer.

A channel semiconductor pattern 127 may be formed in a central region of each of the channel holes, which is opened by the memory layer 125. The channel semiconductor pattern 127 may be formed in a pillar shape filling the central region of each of the channel holes, which is opened by the memory layer 125. Alternatively, the channel semiconductor pattern 127 may be conformally formed along a surface of the memory layer 125, and a central region of each of the channel holes may be opened by the channel semiconductor pattern 127. The central region of each of the channel holes, which is opened by the channel semiconductor pattern 127, may be filled with a core insulating layer 129. The core insulating layer 129 may be formed with a height lower than a height of each of the channel semiconductor pattern 127 and the channel holes. A doped semiconductor pattern 131 may be formed on the core insulating layer 131. The doped semiconductor pattern 131 may be surrounded by an upper end of the channel semiconductor pattern 127 extending longer than the core insulating layer 129.

The channel semiconductor pattern 127 may include a silicon layer. The doped semiconductor pattern 131 may include an n-type doped silicon layer. The core insulating layer 129 may include oxide.

Referring to FIG. 4H, a slit SI penetrating the stack structure (120 shown in FIG. 4G) of the main chip region Main Chip_R may be formed, thereby exposing a sidewall of the stack structure of the main chip region Main Chip_R.

After that, the second material layers (123 shown in FIG. 4G) of the main chip region Main Chip_R, which are exposed through the slit SI, may be removed, and conductive patterns 133 may be formed in spaces in which the second material layers are removed. Each of the conductive patterns 133 may include various conductive materials such as a doped silicon layer, a metal layer, a metal silicide layer, and a barrier layer, and include two or more kinds of conductive materials. For example, each of the conductive patterns 133 may include tungsten and a titanium nitride layer (TiN) surrounding the surface of the tungsten. In an embodiment, the tungsten is a low resistance metal, and may reduce the resistance of the conductive patterns 133. The titanium nitride layer TIN is a barrier layer, and may prevent or mitigate a direct contact between the tungsten and the first material layers 121. The first material layers 121 and the conductive patterns 133, which are alternately stacked, may constitute a cell stack structure 130.

The second material layers 123 formed in the chip guard region CG_R are not etched but may remain. The stack structure 120 including the first material layers 121 and the second material layers 123, which are formed in the chip guard region CG_R, may be defined as a dummy stack structure.

Referring to FIG. 4I, a sidewall insulating layer 135 is formed on a sidewall of the slit SI. The sidewall insulating layer 135 may be formed to expose a bottom surface of the slit SI. The upper semiconductor layer 109 may be exposed through the bottom surface of the slit SI, which is exposed by the sidewall insulating layer 135.

After that, the upper semiconductor layer 109 and the second protective layer 107, which are exposed through the slit SI, may be etched, thereby exposing the sacrificial layer (105 shown in FIG. 4H) of the main chip region Main Chip_R.

After that, a horizontal space 137 may be formed by removing the exposed sacrificial layer 105. In a process of removing the sacrificial layer 105 of the main chip region Main Chip_R, the first protective layer (103 shown in FIG. 4H) and the second protective layer (107 shown in FIG. 4H) of the cell region may prevent or mitigate loss of the upper semiconductor layer 109 and the lower semiconductor layer 101.

After that, a portion of the memory layer exposed through the horizontal space 137 may be etched, thereby exposing the channel semiconductor pattern 127. The memory layer may be divided into a first memory pattern 125a and a second memory pattern 125b through an etching process.

The first protective layer (103 shown in FIG. 4H) and the second protective layer (107 shown in FIG. 4H) may be removed together in the etching process of the memory layer.

Referring to FIG. 4J, a source semiconductor layer 141 may be formed by allowing a conductive material into the horizontal space (137 shown in FIG. 4I) through the slit SI. The source semiconductor layer 141 may be in contact with each of a sidewall of the channel semiconductor pattern 127, the lower semiconductor layer 101, and the upper semiconductor layer 109. The source semiconductor layer 141 may be formed using a chemical vapor deposition technique, or be formed using a growth technique using, as a seed layer, each of the channel semiconductor layer 127, the lower semiconductor layer 101, and the upper semiconductor layer 109. The source semiconductor layer 141 may include a conductivity type dopant. For example, the source semiconductor layer 161 may include an n-type doped silicon layer. The conductivity type dopant in the source semiconductor layer 141 may be diffused into the upper semiconductor layer 109 and the channel semiconductor layer 127, which are in contact with the source semiconductor layer 141, by heat.

After that, a source contact structure 143 which is in contact with the source semiconductor layer 14 and extends onto the sidewall insulating layer 135 may be formed by filling the inside of the slit SI with a conductive material.

Referring to FIG. 4K, a fourth trench T4 may be formed, which exposes the conductive pattern 113 while penetrating the dummy stack structure 120 of the chip guard region CG_R.

In an etching process for forming the fourth trench T4, in an embodiment, stress may occur due to the etching process. However, in an embodiment, stress concentrated on an edge side of the conductive pattern 113 may be distributed by the stress relief pattern 101, 105, and 109 disposed on the sidewall of the conductive pattern 113. In addition, in an embodiment, the stress relief pattern 101, 105, and 109 includes a silicon layer having a relatively high Young's modulus, to absorb the stress, thereby reducing the stress transferred to the periphery thereof. Accordingly, in an embodiment, occurrence of cracks of the semiconductor device due to the stress can be reduced.

After that, a chip guard pattern 151 may be formed by filling a conductive material into the fourth trench T4.

A lower surface of the chip guard pattern 151 may be directly connected to the conductive pattern 113.

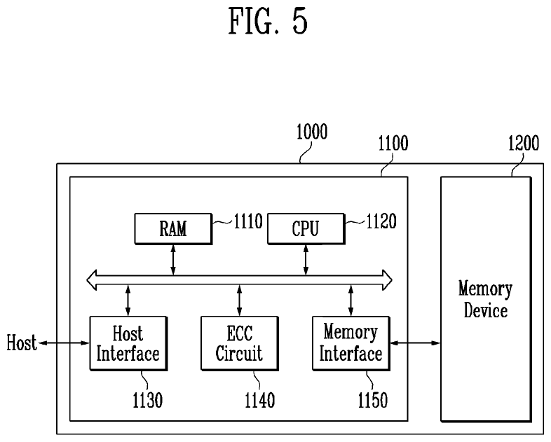

FIG. 5 is a block diagram illustrating a configuration of a memory system in accordance with an embodiment of the present disclosure.

Referring to FIG. 5, the memory system 1000 in accordance with the embodiment of the present disclosure may include a memory device 1200 and a controller 1100.

The memory device 1200 may be used to store data information having various data forms such as texts, graphics, and software codes. The memory device 1200 may be the semiconductor device described above with reference to FIGS. 1 to 3, and be manufactured according to the manufacturing method described above with reference to FIGS. 4A to 4K. A structure and a manufacturing method of the memory device 1200 are the same as described above, and therefore, their detailed descriptions will be omitted.

The controller 1100 may be connected to a host and the memory device 1200, and be configured to access the memory device 1200 in response to a request from the host. For example, the controller 1100 may be configured to control a read operation, a write operation, an erase operation, a background operation, and the like of the memory device 1200.

The controller 1100 may include a Random Access Memory (RAM) 1110, a Central Processing Unit (CPU) 1120, a host interface 1130, an Error Correction Code (ECC) circuit 1140, a memory interface 1150, and the like.

The RAM 1110 may be used as a working memory of the CPU 1120, a cache memory between the memory device 1200 and the host, a buffer memory between the memory device 1200 and the host, or the like. The RAM 1110 may be replaced with a Static Random Access Memory (SRAM), a Read Only Memory (ROM), or the like.

The CPU 1120 may be configured to control overall operations of the controller 1100. For example, the CPU 1120 may be configured to execute firmware such as a Flash Translation Layer (FTL) stored in the RAM 1110.

The host interface 1130 may be configured to perform interfacing with the host. For example, the controller 1100 may communicate with the host through at least one of various interface protocols such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer System Interface (SCSI) protocol, an Enhanced Small Disk Interface (ESDI) protocol, an Integrated Drive Electronics (IDE) protocol, and a private protocol.

The ECC circuit 1140 may be configured to detect an error included in data read from the memory device 1200, using an ECC, and correct the detected error.

The memory interface 1150 may be configured to perform interfacing with the memory device 1200. For example, the memory interface 1150 may include a NAND interface or a NOR interface.

The controller 1100 may include a buffer memory (not shown) for temporarily storing data. The buffer memory may be used to temporarily store data transferred to the outside through the host interface 1130 or to temporarily store data transferred from the memory device 1200 through the memory interface 1150. Also, the controller 1100 may further include a ROM used to store code data for interfacing with the host.

As such, the memory system 1000 in accordance with the embodiment of the present disclosure includes the memory device 1200 having an improved degree of integration and an improved characteristic, and thus the degree of integration and the characteristic of the memory system 1000 can also be improved.

In accordance with an embodiment of the present disclosure, a stress relief pattern is disposed on a sidewall of a conductive contact plug in contact with the bottom of a chip guard pattern, so that stress occurring in an etching process for forming a chip guard pattern can be reduced.

While the present disclosure has been shown and described with reference to certain embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A semiconductor device comprising:
a substrate including a chip guard region;
a stress relief pattern spaced apart from the substrate and disposed over the chip guard region;
a dummy stack structure formed on the stress relief pattern;
a conductive contact plug extending downwardly while penetrating the stress relief pattern; and
a chip guard pattern in direct contact with the conductive contact plug while penetrating the dummy stack structure.

2. The semiconductor device of claim 1, wherein the stress relief pattern surrounds a sidewall of the conductive contact plug.

3. The semiconductor device of claim 1, wherein the stress relief pattern includes a first buffer pattern, a second buffer pattern, and a third buffer pattern, which are sequentially stacked in a vertical direction.

4. The semiconductor device of claim 3, wherein each of the first buffer pattern, the second buffer pattern, and the third buffer pattern includes a doped silicon layer or an undoped silicon layer.

5. The semiconductor device of claim 3, wherein the stress relief pattern includes a first protective layer disposed between the first buffer pattern and the second buffer pattern and a second protective layer disposed between the second buffer pattern and the third buffer pattern.

6. The semiconductor device of claim 1, wherein the substrate of the chip guard region includes a discharge impurity region, and
wherein the conductive contact plug is electrically connected to the discharge impurity region.

7. The semiconductor device of claim 1, wherein the conductive contact plug has substantially a line shape extending in a horizontal direction or has substantially a cylindrical shape.

8. The semiconductor device of claim 3, wherein the substrate further includes a main chip region, and
wherein the semiconductor device further comprises:
a source layer spaced apart from the substrate and disposed over the main chip region; and
a cell stack structure formed on the source layer.

9. The semiconductor device of claim 8, wherein the source layer is disposed at substantially the same level as the stress relief pattern.

10. The semiconductor device of claim 8, wherein the source layer includes a first semiconductor layer, a second semiconductor layer, and a third semiconductor layer, which are sequentially stacked, and
wherein the first semiconductor layer is made of substantially the same material as the first buffer pattern, and the third semiconductor layer is made of substantially the same material as the third buffer pattern.

11. The semiconductor device of claim 1, further comprising an insulating pattern in contact with a sidewall of the stress relief pattern.

12. A semiconductor device comprising:
a substrate including a main chip region and a chip guard region;
a source layer spaced apart from the substrate and disposed over the main chip region;
a cell stack structure formed on the source layer;
a stress relief pattern spaced apart from the substrate and disposed over the chip guard region;
a dummy stack structure formed on the stress relief pattern; and
a conductive contact plug extending downwardly while penetrating the stress relief pattern,
wherein the stress relief pattern includes a doped silicon layer or an undoped silicon layer.

13. The semiconductor device of claim 12, further comprising a chip guard pattern in contact with the conductive contact plug while penetrating the dummy stack structure.

14. The semiconductor device of claim 12, wherein the stress relief pattern includes a first buffer pattern, a second buffer pattern, and a third buffer pattern, which surround a sidewall of the conductive contact plug and are sequentially stacked in a vertical direction.

15. The semiconductor device of claim 14, wherein the source layer includes a first semiconductor layer, a second semiconductor layer, and a third semiconductor layer, which are sequentially stacked, and
wherein the first buffer pattern is made of substantially the same material as the first semiconductor layer, and the third buffer pattern is made of substantially the same material as the third semiconductor layer.

16. The semiconductor device of claim 12, wherein the substrate includes a discharge impurity region, and
wherein the conductive contact plug is electrically connected to the discharge impurity region.

17. The semiconductor device of claim 12, further comprising an insulating pattern disposed on a sidewall of the stress relief pattern.

18. A method of manufacturing a semiconductor device, the method comprising:
forming a source layer on a substrate including a main chip region and a chip guard region;
forming insulating patterns penetrating the source layer of the chip guard region, thereby defining, as a stress relief pattern, the source layer between the insulating patterns;
forming a conductive contact plug penetrating the stress relief pattern;
forming a stack structure, in which first material layers and second material layers are alternately stacked, in the main chip region and the chip guard region over the source layer, stress relief pattern and the conductive contact plug;
forming a trench for chip guard formation, which exposes the conductive contact plug while penetrating the stack structure of the chip guard region; and
forming a chip guard pattern by filling the trench for chip guard formation with a conductive material.

19. The method of claim 18, wherein each of the source layer and the stress relief pattern includes a doped silicon layer or an undoped silicon layer.

20. The method of claim 18, wherein the forming of the conductive contact plug includes:
forming a trench or a hole, which penetrates the stress relief pattern between the insulating patterns; and
forming the conductive contact plug by filling the trench or the hole with a conductive material,
wherein the stress relief pattern surrounds a sidewall of the conductive contact plug.
